(19) United States
(12) Patent Application Publication
(10) Pub. No.: US 2025/0220849 A1
(43) Pub. Date: Jul. 3, 2025

(54) IMMERSION BATCH COOLING APPARATUS FOR ELECTRONIC HARDWARE HAVING DIFFERENT ONBOARD HEAT GENERATING COMPONENTS

(71) Applicant: Submer Technologies SL, Rubí (Barcelona) (ES)

(72) Inventors: Eduard Bosch Coch, Rubí (ES); David Montes Monteserin, Rubí (ES); Ismael Guzman Perez, Rubí (ES)

(21) Appl. No.: 18/866,808

(22) PCT Filed: Apr. 26, 2023
(86) PCT No.: PCT/EP2023/060905

§ 371 Date: Nov. 18, 2024

(30) Foreign Application Priority Data
May 18, 2022 (GB) 2207272.2

(51) Int. Cl. H05K 7/20; G06F 1/20

(52) U.S. Cl. CPC H05K 7/20236; G06F 1/20; H05K 7/20263; H05K 7/20272; H05K 7/20281

(57) ABSTRACT

A liquid cooling apparatus and system for the immersion cooling of electronic devices including in particular servers and other IT hardware nodes having an array of heat generating devices including microprocessors, RAM, motherboards etc having different operational temperatures. The present apparatus and system is adapted for at least an in-series flow of cooling liquid in direct contact with the different heat generating devices so as to provide multi-stage heat transfer phases for enhanced energy efficiency and operational control and performance of the electronic device.

### FIELD OF CONCEPT

The present concept relates to a liquid cooling system for the effective and efficient refrigeration of heat-generating electronic components and in particular, although not exclusively, to a liquid refrigeration system to cool IT components, servers, computational electronic devices and the like via direct submersion of such components and devices in a dielectric liquid coolant.

### BACKGROUND

The cooling of electronics, specifically IT components, servers, data storage devices and computational electronic devices having graphics and central processing units (GPUs and CPUs) has become a major technical challenge due to the ongoing development of smaller, faster, higher density and higher power capacity electronics.

Computing devices produce heat as a by-product of operational processing. In datacentres, where thousands of such devices are located, the amount of heat generated can be extremely large. As the need for access to greater processing and data storage continues to expand, the density of server systems continues to increase, and the resulting thermal challenges present a significant practical obstacle.

Conventional fan-based cooling systems require large amounts of power. Accordingly, the power demand to drive such systems increases significantly with the increased server densities. Immersion cooling of IT components is a relatively recent development. The operational hot electronics are submerged in direct contact with a dielectric (electrically insulating) coolant liquid that is circulated and cooled through the use of heat exchangers and the likes. Cooling of electronics enhances their performance efficiency enabling higher processing speeds (for example the overclocking of CPUs). The heat generated by the circuit is removed quickly and efficiently by the dielectric liquid directly at the heat source. However, there is a general need for continued improvement of the operational efficiency of existing liquid submersion cooling systems with regard to both the effectiveness of the cooling of the electronic components and also the thermal management and circulation of the coolant liquid for efficient energy reuse.

### SUMMARY OF THE CONCEPT

It is an object of the present disclosure to provide an apparatus and a method for the precise and efficient liquid cooling of electronic devices. It is a specific objective to provide an electronic component liquid cooling system to enable IT components and the like to operate at high temperatures. It is a further specific objective to provide a refrigeration system to maximise the working temperature of the dielectric liquid due to heat transfer with the electronic components for subsequent energy reuse. It is a further specific objective to provide a system to provide an outflow of the dielectric liquid (following heat transfer with the electronic component) at a uniform/constant temperature. Such a configuration maximises the efficiency and effectiveness of the heat energy transfer with a suitable heat exchanger or the like for heat-energy reuse.

The present system provides a liquid submersion/immersion arrangement in which IT electronic components are partitioned/segregated spatially based in their operating temperature and effective power-draw. In particular, the present system is configured for electronic component cooling via direct contact and circulation with the refrigerant liquid to provide a single-liquid refrigeration system for the cooling-on-demand of each electronic component individually and/or independently of one another according to operational performance, type, operating temperature, size and/or configuration of the electronic component.

Reference within this specification to an ‘electronic component’, an ‘electronic device’ or similar, encompasses a heat-generating electronic component for example mounted at a larger IT component/device such as a server, motherboard, data storage device, programmable logic controller board etc. Such heat-generating electronic components include for example the circuitry and/or electronics at a motherboard or other printed circuit board device, random access memory (RAM); graphics processing unit (GPU); central processing unit (CPU); chips, sockets; peripheral component interconnect (PCI) slots; read-only memory (ROM) components, chips and slots; graphics processing components, ports, slots, chips; electronic bridges; battery components, ports and slots; power supply plugs, slots and ports, electronic connectors; electronic heatsinks; switches; jumpers; capacitors; transistors; diodes; operational power associated components; current and/or voltage regulators and modules; power supply convertors etc.

The present system is configured to deliver the coolant liquid to the heat-generating electronic devices based on their typical, normal, average or maximum operating temperature according to a variety of different possible liquid flow circuit configurations. For example, the present system is compatible with in-series, in-parallel and/or combined in-series and in-parallel liquid flow configurations based on the spatial positioning of the electronic components according to their typical, normal, average and/or maximum operating temperature. Accordingly, the present system provides an outgoing liquid flow at a maximised outflow temperature and at a constant/uniform temperature over time. The heated dielectric liquid may then be processed efficiently and effectively for heat-reuse via a heat exchanger or the like with the heat energy transferred from the dielectric liquid to an auxiliary application or device that requires a temporary or continuous supply of heat energy.

The outflow of the dielectric liquid heated to a maximum and uniform working temperature (over time) provides an efficient and effective source of heat for heat reuse technologies. This is achieved via the spatial partitioning/segregation of the heat-generating devices based on their respective operating temperatures. In particular, at least one and in particular a set of first heat-generating electronic components may be partitioned and located within a first region or chamber of the apparatus for a first contact with the dielectric liquid. At least one second component or set of further heat-generating electronic components (having a higher operating temperature than the first electronic devices) may be located at a segregated or partitioned region (or enclosure) of the system/apparatus for separate and/or subsequent contact with the dielectric liquid. Such an arrangement allows the dielectric liquid to flow in direct contact with the first heat-generating electronic components and then the second heat-generating electronic components such that the temperature of the dielectric liquid output at an outflow region of the apparatus is the sum of the temperature increase of the liquid having passed in contact with the electronics at all the spatially segregated regions.

In one aspect, the present system includes an encapsulation (or cover) positionable to enclose (at least partially) an electronic device e.g., a CPU/GPU. This encapsulation may be installed over a chip (with or without the heatsink) or on the top of the chip (e.g., cold-plate technology). The coolant is then be configured to flow through each encapsulation region to capture all the heat generated by the electronic device. Such an arrangement enables the electronic device (GPU/CPU) to operate at its optimal or typical operating temperature independently of an overclocking mode whilst also allowing the temperature of an outgoing flow of the coolant liquid to be as high as possible and uniform over time for improved energy reuse.

In one aspect, the present system provides that the submerged heat generation devices are segregated according to their operating temperature range, so that all of them are in contact with a different portion of the cooling fluid within the fluid container at a given time. The fluid within the container is driven to a cooling device where it is cooled down ready to be driven again into the container, therefore effectively cooling down the submerged heat generation devices in-series. The fluid may be driven in such a way through the system so that it first contacts the segregated heat generation devices with the lowest operating temperature. Then, the partially heated fluid is driven in contact with a next set of segregated heat generation devices with the second lowest operating temperature, where its temperature may increase further. This is repeated until the set of segregated heat generation devices with the highest operating temperature is contacted by the dielectric liquid, which is then driven to a cooling device (i.e., heat exchanger).

According to a first aspect of the present concept there is provided liquid cooling apparatus for an electronic device comprising: a primary housing defining a chamber to accommodate at least one electronic device having at least one heat-generating electronic component; at least one liquid flow inlet and at least one liquid flow outlet provided at the housing to allow a flow of a dielectric cooling liquid to enter and exit the chamber in direct contact with the electronic device; a second housing located within the chamber defining an enclosure to at least partially accommodate the at least one heat-generating electronic component of the device; at least one liquid flow inlet and at least one liquid flow outlet provided at the second housing to allow a flow of the liquid to enter and exit the enclosure in direct contact with the heat-generating electronic component; and a cooling unit connected in fluid communication with at least one of the inlets and at least one of the outlets forming part of a fluid flow network to transfer heat energy from the liquid.

Preferably, the at least one outlet of the primary housing is connected in fluid communication to the at least one inlet of the second housing such that the liquid is configured to flow through the chamber and then through the enclosure.

Preferably, the electronic device comprises at least one first heat-generating electronic component at least partially accommodated within the chamber for immersion in the liquid within the chamber; and at least one second heat-generating electronic component at least partially accommodated within the enclosure for immersion in the liquid within the enclosure. Optionally, the second heat-generating electronic component is capable of comprises a higher operating temperature than the first heat-generating electronic component.

Reference within this specification to a first heat-generating electronic component encompasses relatively low heat generating devices/components (LHGDs) for example RAM, the motherboard and the like. Likewise reference herein to a second heat-generating electronic component encompasses relatively high heat-generating components (HHGDs) for example microprocessors, CPUs, GPUs and the like. The first and second heat-generating electronic components are differentiated herein by their relative normal, typical, standard and/or maximum operating temperatures. This is the heat energy such devices generate in use and/or as detailed in electronic component datasheets, databases and the like. Accordingly, the low heat generating components/devices generally comprises a normal, typical, standard and/or maximum operating temperature that is below that of the high heat-generating components/devices. In certain specific implementations, a low heat generating component/device may be configured to generate heat under normal or typical operation that is less than 200W. Moreover, in certain specific implementations, a high heat generating component/device may be configured to generate heat under normal or typical operation that is more than 200W. However, such values are given for guidance only and the skilled person will understand this value of 200W as applied to the LGHD and HHGDs herein may different specific to the type of electronic component.

Preferably, the at least one outlet of the second housing is connected in fluid communication to an inlet of the cooling unit and an outlet of the cooling unit is connected in fluid communication to the at least one inlet of the primary housing. Optionally, the chamber is connected in fluid communication in-series with the enclosure.

Preferably, the apparatus comprises at least one electronically controllable valve provided in fluid communication with the inlet and/or the outlet of the primary housing and/or the second housing; and a control unit to control the valve and a flow of the liquid to enter and exit the primary housing and/or the second housing via the respective inlet and outlet.

Optionally, the control unit is configured to control the liquid flow through the chamber for a first heat energy exchange with the first heat-generating electronic component and then to control the liquid flow through the enclosure for a second heat energy exchange with the second heat-generating electronic component, the second heat energy exchange being supplemental and additional to the first heat energy exchange such that an increase in a temperature of the liquid at the outlet of the enclosure is a sum of a temperature increase of the liquid having passed through the chamber and the enclosure. The control unit may comprise one or a plurality of electronic control units, modules or devices that may include a programmable logic controller (PLC), a remote telemetry unit (RTU), a microprocessor, a server, a printed circuit board, a motherboard or other similar device. The control unit may comprise sensors that include at least one flow rate, temperature, proximity, motion, current, voltage, pH and/or magnet sensor. The control unit may comprise at least one control valve that may comprise a solenoid valve, a diaphragm valve, a pilot-operated, plural-way valve and combinations thereof. The control unit may be located locally or remote to the present system and apparatus for the local and/or remote control of the apparatus. The control unit may be operated via a cloud network, wireless or wired communication pathways and associated components.

Preferably, the primary housing comprises a liquid immersion tank. Preferably, the at least one second housing is smaller in size than the primary housing and is located within the chamber. Optionally, the apparatus comprises a plurality of second housings (alternatively referred to herein as enclosures) that may be positioned in-series and/or in-parallel with one another. Accordingly, liquid may be configured to flow through the chamber according to a first pathway and then to flow through at least one enclosure via a second pathway in-series and then to flow through a further enclosure in-series with the first enclosure. Each enclosure may comprise the same or different heat-generating electronic components having the same or different operating temperatures. When the enclosures are connected in-parallel, the liquid supply may be divided/split into separate streams flowing into each of the respective enclosures in-parallel. The separated parallel flow streams may be then combined to a single flow stream after flowing through the enclosures (in a fluid flow direction).

Optionally, the present system may comprise a plurality of enclosures defined by respective second housings each enclosing a respective heat-generating electronic component provided at the electronic device; the plurality of enclosures arranged in a fluid flow direction in parallel and/or in series with one another. Optionally, the respective heat-generating electronic components may comprise substantially the same operating temperature or may comprise different operating temperatures arranged within respective second housings in order of increasing operating temperature. Optionally, the liquid is capable of flowing through the respective second housings in contact with the respective heat-generating electronic components in parallel or in series. Preferably, the primary housing comprises an immersion tank or bath and the second housing comprises at least one second housing, shroud, container, pocket or sub-chamber to contain respectively the different heat generating electronic components being spatially partitioned relative to the larger primary housing allowing a partitioned/separated liquid flow in contact with the different (sets of) electronic devices. Optionally, the second housing may be contained exclusively and/or entirely within the primary housing.

The apparatus typically comprises a dielectric cooling liquid contained within the chamber of the primary housing and wherein the second housing is at least partially immersed in or completely submerged by the liquid within the chamber of the primary housing. The dielectric cooling liquid may be any liquid type suitable for immersion cooling of IT components having appropriate electrically insulating characteristics to provide safe direct contact with energised electronic components importantly with no liquid electrical conductivity.

Optionally, at least a part of the second heat-generating electronic component is positioned in direct contact with the liquid within the enclosure defined by the second housing and/or at least a part of the first heat-generating electronic component is positioned in direct contact with the liquid within the chamber.

Optionally, the electronic device may comprise any one or a combination of: a computer entity; a server; a motherboard; a printed circuit board comprising a plurality of electronic components. Optionally, the first heat-generating electronic component and/or the second heat-generating electronic component comprise any one or a combination of: a motherboard; random access memory (RAM); a graphics processing unit (GPU); a central processing unit (CPU).

Optionally, the inlet of the second housing is defined by at least a perimeter of an opening by which the second housing is positionable to receive and envelope the heat-generating electronic component at the enclosure. Optionally, the inlet and outlet of the second housing are separate from one another and/or positioned at different regions of the second housing. Optionally, the second housing comprises an opening to enable the second housing to receive and envelope the heat-generating electronic component at the enclosure and a roof positioned opposite the opening. Optionally, the inlet of the second housing is positioned at the roof of the second housing. Optionally, the outlet of the second housing is defined, in part by the opening. Optionally, the inlet and/or outlet of the second housing is defined, in part, by a perimeter of the opening of the second housing. Optionally, the inlet and/or outlet of the second housing is defined, in part, by a gap or region between an outer perimeter of the electronic component and the region immediately inside the perimeter of the enclosure. Such a gap region may be annular such that the liquid flow into and/or from the enclosure occurs via the space/gap between the electronic component and the wall or body of the second housing.

Optionally, the second housing is adjustably mounted at the apparatus via an actuator that by actuation is configured to change an internal volume of the enclosure. Optionally, the apparatus comprises an actuator connected to the second housing to actuate a movement of the second housing, the actuator configured to change any one or a combination of: an internal volume of the enclosure; a position of the enclosure relative to the housing and/or the heat-generating electronic component; a separation distance between the second housing and the heat-generating electronic component; an extent to which the second housing encapsulates or accommodates the heat-generating electronic component within the enclosure. The actuator may comprise an electronic actuator, a magnetic actuator, a pneumatic or hydraulic actuator, a combination of such actuators including optionally an electromagnetic or electromechanical actuator controlled locally or remotely via the control unit.

Optionally, the apparatus comprises a pump connected in fluid communication to the inlet and/or the outlet of the second housing to drive a flow of the liquid through the enclosure.

Optionally, the apparatus comprises a first electronically controllable valve connected in fluid communication to the inlet and/or the outlet of the chamber and a second electronically controllable valve connected in fluid communication to the inlet and/or the outlet of the enclosure. Optionally, the apparatus further comprises at least one electronically controllable valve provided in fluid communication with the inlet and/or the outlet of the second housing.

Optionally, the apparatus further comprises at least one temperature sensor to determine a temperature or relative temperature difference of the liquid and/or the heat-generating electronic component, the temperature sensor provided in electronic communication with the control unit. Optionally, the electronic device or the first and/or second heat-generating electronic components comprise a temperature sensor to determine a temperature or a temperature difference of the liquid and the first and/or second heat-generating electronic components. Optionally, the apparatus comprises at least one sensor. Optionally, the at least one sensor may comprise at least one flow rate, temperature, proximity, motion, current, voltage, pH and/or magnet sensor.

Optionally, the apparatus comprises a liquid return conduit connecting in fluid communication the outlet of the chamber and the inlet of the enclosure to circulate the liquid that exits the chamber into the enclosure. Optionally, the apparatus comprises a temporary storage reservoir connected in fluid communication between the outlet of the chamber and the inlet of the enclosure to temporarily store a volume of the liquid for circulation from the chamber to the enclosure. Optionally, an inlet of the chamber comprises a plenum to distribute a flow of the liquid into the chamber.

Optionally, the cooling unit comprises a heat exchanger to transfer heat energy from the liquid to a heat transfer fluid. Optionally, the heat exchanger comprises a refrigerant fluid configured for circulation within a fluid circuit or network being separate to a dielectric liquid and the dielectric liquid network configured to flow through the chamber and the enclosures. These exchanges configured to allow thermal energy transfer between the dielectric liquid and the refrigerant fluid and in particular the transfer of heat energy from the dielectric liquid to the refrigerant working fluid.

Preferably, the outlet of the primary housing is connected in fluid communication to an inlet of the cooling unit and an outlet of the cooling unit is connected in fluid communication to the inlet of the second housing.

Optionally, the apparatus comprises a plurality of second housings, each having a respective inlet and outlet connected in fluid communication to the cooling unit. Optionally, at least some of the second housings are connected in-series with one another as part of a liquid flow network including the cooling unit. Optionally, at least some of the second housings are connected in-parallel with one another as part of a liquid flow network including the cooling unit.

Optionally, a dielectric cooling liquid is contained within the chamber and capable of flowing through the enclosure. Optionally, at least a part of the electronic device and/or the at least a part of first heat-generating electronic component is positioned within the chamber and immersed in direct contact with the liquid within the chamber and at least a part of the at least one second heat-generating electronic component is positioned within the enclosure and immersed in direct contact with the liquid within the enclosure.

Optionally, the apparatus comprises at least one weir arrangement provided in fluid communication with the inlet and/or the outlet of the primary housing and/or the second housing. Optionally, the apparatus comprises a first weir arrangement provided in fluid communication with the inlet and/or the outlet of the second housing. Optionally, the apparatus may comprise a second weir arrangement provided in fluid communication with the inlet and/or the outlet of the primary housing. Reference within the specification to ‘a weir arrangement’ encompasses at least one aperture, partition wall, flow restriction body and the like configured to at least partially separate a first volume of liquid from a second volume of liquid such that liquid is configured to flow from the first volume to the second volume via a restricted flow pathway at the weir arrangement. Such an arrangement encompasses an overflow or through-flow arrangement. Optionally, the weir arrangement may provide the over- or through-flow under gravity.

Optionally, the apparatus comprises at least one storage reservoir connected in fluid communication to the chamber to feed and/or receive the liquid at the chamber and to maintain a pre-determined volume of liquid at the chamber. Optionally, the apparatus may comprise at least one main storage reservoir connected in fluid communication to at least one of the inlet and outlet of the enclosure/second housing to store the liquid as part of a fluid flow network. Optionally, the main storage reservoir comprises a pressurisation mechanism to change a pressure of the liquid within the fluid flow network. Optionally, the pressurisation mechanism comprises at least one electronically controllable valve to control a volume of liquid within the main storage reservoir and/or the fluid flow network.

According to a further aspect of the present concept there is provided a method of cooling at least part of an electronic device comprising: immersing an electronic device having at least one heat-generating electronic component within a dielectric cooling liquid contained within a chamber defined by a primary housing; immersing the heat-generating electronic component within the liquid within an enclosure defined by a second housing located within the chamber; providing a first flow of the liquid through the chamber via at least one inlet and at least one outlet provided at the primary housing; providing a second flow of the liquid through the enclosure via at least one inlet and at least one outlet provided at the second housing; cooling the liquid heated by the electronic device and/or the heat-generating electronic component using a cooling device forming part of a fluid flow network connected in fluid communication to at least one of the inlets and at least one of the outlets.

Optionally, the electronic device comprises at least a first heat-generating electronic component and at least one second heat-generating electronic component that is capable of or comprises a higher operating temperature than the first heat-generating electronic component, wherein at least a part of the second heat-generating electronic component is positioned in direct contact with the liquid within the enclosure defined by the second housing and/or at least a part of the first heat-generating electronic component is positioned in direct contact with the liquid within the chamber.

Optionally, the chamber is connected in fluid communication in-series with the enclosure such that the liquid is configured to flow through the chamber and then to flow through the enclosure.

Optionally, the method comprises plurality of enclosures defined by respective second housings each enclosing a respective heat-generating electronic component provided at the electronic device; wherein the plurality of enclosures are connected in liquid flow in-series with one another; and wherein the respective heat-generating electronic components comprise substantially the same operating temperature or comprise different operating temperatures arranged within respective second housings in order of increasing operating temperature such that the liquid is configured to flow through the respective enclosures in contact with the respective heat-generating electronic components in-series from the relative low to high operating temperature.

Optionally, the liquid is configured to flow from the outlet of the chamber to the inlet of the enclosure via a return flow conduit and then the liquid is configured to flow from the at least one outlet of the enclosure to a fluid flow network that includes the cooling unit.

Optionally, the method comprises controlling a flow of the liquid to flow along the first pathway through the chamber in direct contact with at least a part of the first heat-generating electronic component and then along a second flow pathway through the enclosure in direct contact with at least a part of the second heat-generating electronic component such that heat energy transferred to the liquid is a sum of a heat energy transferred from the first heat-generating electronic component and the second heat-generating electronic component.

Preferably, the method comprises driving a flow of the liquid through the chamber and/or the enclosure using a pump. Preferably, the method comprises directing a return flow of the liquid from the outlet of the chamber at an end of the first flow pathway to the inlet of the enclosure at a start of the second flow pathway. Preferably, the method further comprises directing the flow of the liquid from the outlet of the enclosure to the cooling unit to reduce the temperature of the liquid; and providing a return flow of the liquid cooled by the cooling unit to the inlet of the enclosure.

Optionally, the method comprises temporarily storing the liquid received from the outlet of the chamber at the end of the first flow pathway at a temperature storage reservoir prior to the step of directing the return flow of the liquid to the inlet of the enclosure. Optionally, the electronic device comprises a plurality of first heat-generating electronic components each immersed in the liquid and a plurality of second housings defining respective enclosures to accommodate the heat-generating electronic components. Optionally, the liquid flows through the enclosures in direct contact with the heat-generating electronic components and the flow through some of the enclosures is in-series and/or the flow through some of the enclosures is in-parallel.

According to a further aspect of the present concept there is provided a liquid immersion cooling bath to cool an electronic device having at least one heat-generating electronic component, the bath comprising the apparatus as described and claimed herein; and an electronic device having at least one heat-generating electronic component, the device and the heat-generating electronic component immersed respectively within the dielectric cooling liquid contained within the chamber as defined by the primary housing and/or the enclosure as defined by the second housing.

Optionally, the liquid immersion cooling bath comprises at least one primary housing defining the chamber to accommodate the at least one electronic device having at least one heat-generating electronic component; a plurality of second housings located within the chamber defining respective enclosures to at least partially accommodate respective heat-generating electronic component of the devices; and a plurality of electronic devices each having at least one heat-generating electronic component, the devices immersed within the liquid contained within the chamber and the at least one heat-generating electronic component immersed within the liquid contained within the respectively enclosures.

Optionally, the liquid immersion cooling bath comprises a plurality of electronic devices each have first and second heat-generating electronic components, the devices and the first heat-generating electronic components at least partially immersed within or completely submerged by the liquid contained within the primary housing and the second heat-generating electronic components at least partially immersed within or completely submerged by the liquid contained within the enclosures.

### BRIEF DESCRIPTION OF DRAWINGS

A specific implementation of the present invention will now be described, by way of example only, and with reference to the accompanying drawings in which:

FIG. 1 is a perspective view of an immersion cooling bath to house a plurality of IT hardware nodes each having an array of microprocessors according to a specific implementation of the present concept;

FIG. 2 is a perspective view of a rack to mount the plurality of IT hardware nodes of FIG. 1 in a vertical arrangement according to a further implementation of the present concept;

FIG. 3 is a schematic view of precision segregated cooling apparatus to cool a respective first and second heat generating electronic component mounted on an IT hardware node;

FIG. 4 is a schematic view of selected components of a precision segregated cooling system having a circulating fluid network to circulate a cooling liquid in direct contact with a plurality of heat generating electronic components;

FIG. 5 is a schematic view of selected components of a precision segregated cooling system configured to deliver a cooling liquid to a low heat generating device and a plurality of high heat generating devices mounted an IT hardware node;

FIG. 6 is a further schematic view of selected components of a precision segregated cooling system configured to deliver a cooling liquid in-series to an IT hardware node and heat generating devices of FIG. 5;

FIG. 7 is a schematic view of a plurality of adjustably mounted second housings configured to receive a cooling liquid to cool a plurality of heat generating devices an IT hardware node;

FIG. 8 is a schematic view of an enclosure encapsulating a high heat generating device and having a control valve at the inlet of the enclosure to regulate the flow of a cooling liquid;

FIG. 9 is a schematic view of the enclosure and heat generating device of FIG. 8 with the enclosure moved to a lowered position to reduce an internal volume within the enclosure;

FIG. 10 is a further schematic view of the arrangement of FIG. 8 with the enclosure raised to increase the internal volume of the enclosure;

FIG. 11 is a perspective view of a tray to accommodate an IT hardware node having a plurality of microprocessors, the tray provided with internal partitioning weir walls for a controlled circulation of a cooling liquid;

FIG. 12a is a cross sectional side view of a first arrangement of a weir for the controlled circulation of a cooling liquid at an IT hardware node;

FIG. 12b is a cross sectional side view of a second arrangement of a weir for the controlled circulation of a cooling liquid at an IT hardware node;

FIG. 12c is a cross sectional side view of a third arrangement of a weir for the controlled circulation of a cooling liquid at an IT hardware node;

FIG. 13 is a schematic view of an immersion cooling system having an IT hardware node submerged within a cooling liquid contained within an immersion cooling bath and coupled to a circulating cooling fluid network and manifold according to a specific implementation of the present concept;

FIG. 14 is a schematic illustration of a cooling fluid circulation system for the partitioned delivery and circulation of cooling liquid at respective heat generating devices mounted at an IT hardware node according to one specific implementation of the present concept;

FIG. 15 is a schematic illustration of a cooling fluid circulation system for the partitioned delivery and circulation of cooling liquid at respective heat generating devices mounted at an IT hardware node according to a further specific implementation of the present concept;

FIG. 16 is a schematic illustration of a cooling fluid circulation system for the partitioned delivery and circulation of cooling liquid at respective heat generating devices mounted at an IT hardware node according to a further specific implementation of the present concept;

FIG. 17 is a schematic illustration of a cooling fluid circulation system for the partitioned delivery and circulation of cooling liquid at respective heat generating devices mounted at an IT hardware node according to a further specific implementation of the present concept;

FIG. 18 is a schematic illustration of a cooling fluid circulation system for the partitioned delivery and circulation of cooling liquid at respective heat generating devices mounted at an IT hardware node according to a further specific implementation of the present concept;

FIG. 19 is a schematic illustration of a cooling fluid circulation system for the partitioned delivery and circulation of cooling liquid at respective heat generating devices mounted at an IT hardware node according to a further specific implementation of the present concept.

### DETAILED DESCRIPTION OF PREFERRED EMBODIMENT OF THE CONCEPT

The present partitioned cooling fluid system seeks to maximise the energy efficiency within a circulating cooling liquid network via the segregated/partitioned delivery of a working liquid to an array of on-board heat generating devices (typically microprocessors) differentiated by their or typical operating temperatures. In particular, the present system provides a multi-stage, in-series cooling liquid circulation network in which a dielectric cooling liquid may be delivered via an initial flow path in direct contact with at least one heat generating device having a relative low operating temperature and then to flow via a second flow path in direct contact with at least one or a plurality of heat generating devices (approximately co-located with the low heat generating devices) such that a transfer of heat energy from the low and then the high heat generating devices occur in-series as a multi-stage heat transfer process. This configuration maximises the temperature change of the circulated cooling liquid. The present system may be implemented either within an immersion cooling bath or a more conventional IT hardware node rack.

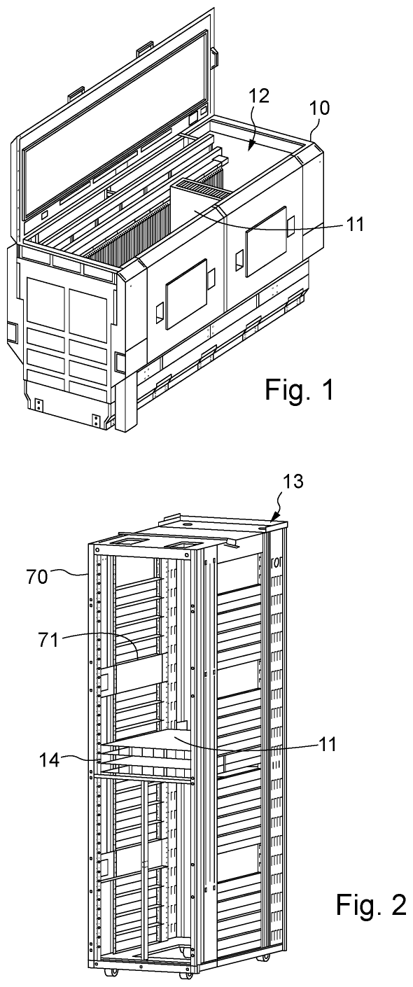

Referring to FIG. 1, an immersion cooling bath 10 comprises an internal chamber 12 to accommodate a plurality of IT hardware nodes 11 (such as servers and the like), each having an array of different heat generating devices (HGDs) in the form of on-board electronic components that may typically comprise relatively low heat generating components (e.g., RAM, the motherboard and the like) and relatively high heat generating devices (e.g., microprocessors) that themselves may have different maximum operating temperatures. FIG. 2 illustrates an alternative arrangement for mounting IT hardware nodes 11 in the form of a support rack 13 in which the IT hardware nodes 11 are mounted within a generally upstanding frame 70. A plurality of horizontal rails 71 allow the mounting of respective trays 14, with each tray configured to accommodate at least one IT hardware node 11 so as to provide an array of nodes 11 mounted the rack 13 vertically relative to one another.

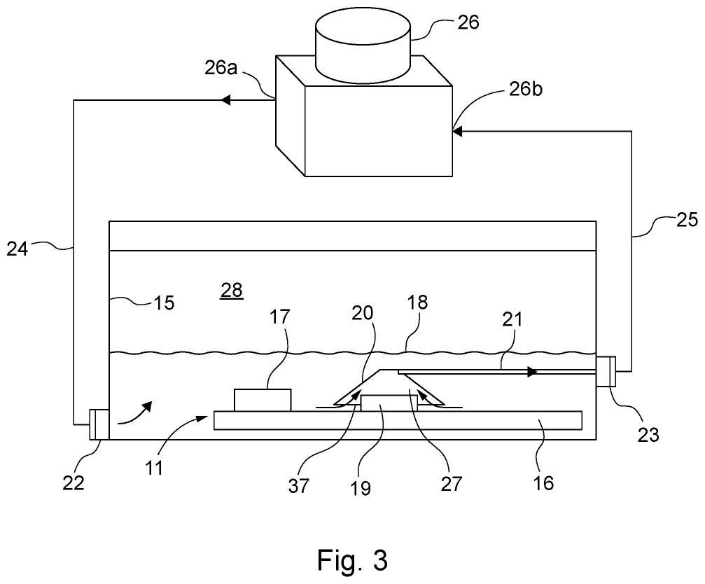

Referring to FIG. 3, the present system comprises a primary housing 15 that defines an internal chamber 28 to contain a dielectric cooling liquid 18. Primary housing 15 is sized so as to accommodate an IT hardware node and in particular an electronic device such as a motherboard 16 that in turn mounts a plurality of electronic components including specifically a plurality of low heat generating devices 17 (LHGDs) and a plurality of high heat generating devices 19 (HHGDs). For ease of illustration FIG. 3 shows a single LHGD 17 and HHGD 19 and a respective single second housing 20. However, it would be appreciated the present apparatus comprises a plurality of such components. A plurality of second housings (alternatively termed covers) 20 are positioned over and about each of respective HHGDs 19. A conduit 21 provides fluid communication between an outlet port 23 of primary housing 15 and respective enclosures 27 defined by each second housing 20. Each second housing 20 comprises an opening 37 having a cross sectional area greater than the size/cross sectional area of each HHGD 19. Accordingly, at least a part of each HHGD 19 may be accommodated or housed within each enclosure 27 as defined by each second housing 20 that is positioned over and about each HHGD 19. Each opening 37 is accordingly positioned in touching or near touching contact with motherboard 16 at the region immediately surrounding each HHGD 19. Primary housing 15 also comprises an inlet 22 at a respective opposite end relative to outlet 23. An inlet manifold 24 is connected in fluid communication between inlet 22 and a heat exchanger 26 having a respective outlet 26a and inlet 26b. A corresponding return manifold 25 provides fluid communication between housing outlet 23 and the heat exchanger inlet 26b. Accordingly, a dielectric cooling liquid is configured for circulation through chamber 28 and in direct contact with the LHGDs 17 and HHGDs 19 (via inlet 22 and outlet 23), heat exchanger 26 and manifolds 25 and 24. Heat exchanger 26 comprises an internal heating coil having a corresponding working fluid or other similar arrangement configured for the transfer of energy from the dielectric cooling liquid received at inlet 26b such that the temperature of liquid output at outlet 26a is lower than the temperature of the in-flowing liquid (through inlet 26b).

According to the in-series partitioned immersion cooling of the respective LHGDs 17 and HHGDs 19, the temperature differential of the liquid at outlet 23 and inlet 22 is maximised that, in turn, maximises the energy efficiency of the present arrangement. In particular, according to the arrangement of FIG. 3, the cooling liquid enters chamber 28 via inlet 22, the liquid then contacts the LHGDs 17 for a first energy exchange whereby the dielectric liquid temperature is increased slightly. The partially warmed liquid, due to suction forces, is drawn into enclosures 27 via each opening 37. The liquid contained within each second housing 20 undergoes a second stage energy exchange with the HHGDs 19 operating at a much higher temperature relative to the LHGDs 17. Accordingly, the already warmed liquid is heated further to its maximum working temperature. The fluid is then output from the enclosure 27 (and the chamber 28) and is delivered to the heat exchanger 26 via outlet 23 and return manifold 25. Once cooled within the heat exchanger 26, the dielectric liquid is then recirculated to the inlet 22 via inlet manifold 24 and the cycle repeated.

According to the various embodiments described herein, the present apparatus and system comprises a control unit, sensors and electronically controllable fluid flow valves so as to control and regulate a flow rate of the dielectric liquid flowing through the various regions of the apparatus and to maximise energy efficiency and in particular a desired heat energy exchange with the LHGDs 17 and HHGDs 19. The control unit may comprise a programmable logic controller (PLC), a remote telemetry unit (RTU), a microprocessor and/or a motherboard and the like. The sensors may comprise flow rate, temperature, proximity, motion, current, voltage, pH, and/or magnetism sensors. The control valves may comprise a solenoid valve, a diaphragm valve, or other electromagnetic valve including by way of example direct actuating, pilot-operated, two-way, three-way, four-way valves and combinations thereof. The present system and apparatus may be controlled locally and/or remotely via a cloud network and is configurable for the local or remote monitoring of the various operational characteristics of the present system and apparatus including operational performance of the electronic components and/or the dielectric cooling fluid.

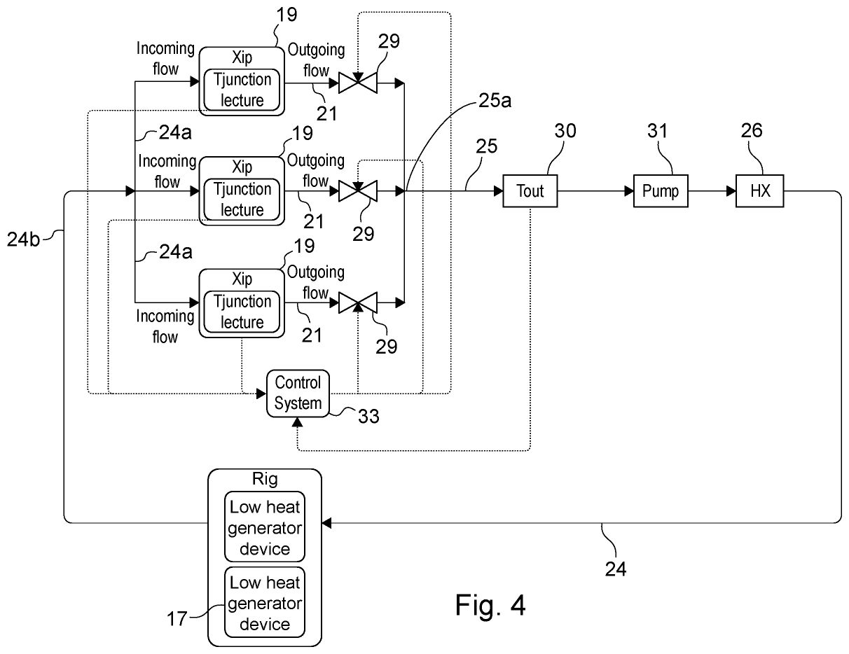

Referring to FIG. 4, the present apparatus is configured to achieve the maximum temperature change of a dielectric cooling liquid (delivered in direct contact with a plurality of the LHGDs 17 and HHGDs 19) in addition to supplying to a heat exchanger the cooling liquid at a constant temperature. Such a configuration maximises the operational performance of the heat exchanger and the present system. According to the arrangement of FIG. 4, an inlet manifold 24 provides fluid communication between a plurality of the LHGDs 17 and a plurality of spatially partitioned HHGDs 19 (all mounted on-board an IT hardware node). Each HHGD 19 is encapsulated, at least partially, by a respective second housing 20 (FIG. 3). In particular, the incoming cooling liquid is divided via inlet conduits 24a so as to provide parallel liquid flow streams to each of the enclosures 27 accommodating each HHGD 19. The heated fluid is then output from each respective enclosure 27 via conduits 21. Flow control valves 29 are coupled in electronic communication with a control unit 33 that is also provided with suitable sensors (not shown) to monitor at least one operational characteristic at each HHGD 19 and/or region of enclosure 27 including in particular a flow rate, temperature and/or temperature change of the cooling liquid at each HHGD 19. The flow streams from conduits 21 are then configured to converge via outlet conduits 25a to provide a single flow stream to the return manifold 25. A temperature sensor 30 (electronically coupled to control unit 33) is provided at manifold 25. A pump 31 drives the flow of the liquid through the circuit and in particular in direct contact with the LHGDs 17 and HHGDs 19 and onwards to heat exchanger 26. Inlet manifold 24 provides the return flow from heat exchanger 26 to the LHGDs 17 for the first stage heat energy exchange prior flow to the HHGDs 19.

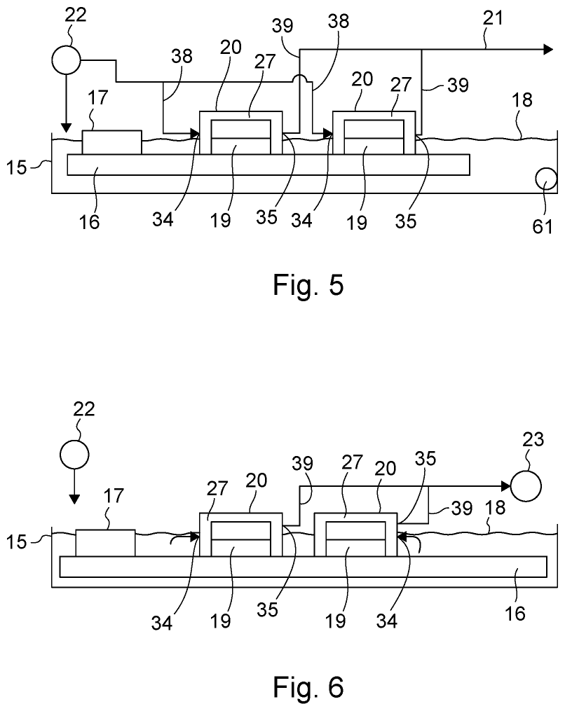

Referring to FIG. 5, a specific implementation of the flow pathway at the LHGDs 17 and HHGDs 19 is described. The cooling liquid 18 within primary housing 15 is delivered in direct contact with the LHGDs 17 for the first stage heat transfer. The partially heated liquid is then output via outlet 61 at primary housing 15. This partially heated fluid may then be returned to inlet 22 via a return manifold. The liquid is then be divided for further heat energy exchange with the LHGDs 17 whilst also being transferred via conduits 38 to the second housings 20 positioned over and about respective HHGDs 19. The partially warmed liquid enters enclosures 27 via respective inlets 34, flows in direct contact with a respective HHGD 19 and then exits enclosure 27 via respective outlet 35. The dielectric liquid is thereby heated to its maximum working temperature. Outlet conduits 39 provide fluid communication between each enclosure 27 (defined by second housings 20) to a single combined outlet conduit 21 which in turn is provided in fluid communication with heat exchanger 26. With the implementation of FIG. 5, the dielectric liquid is delivered specifically to reach enclosure 27 via respective conduits 38.

A variation of the embodiment of FIG. 5 is illustrated according to FIG. 6. In this arrangement, the dielectric liquid 18 within primary housing 15 undergoes the first stage heat transfer with the LHGD 17. The partially warmed liquid is then drawn into each respective enclosure 27 via respective inlet ports 34 that are at least partially submerged within the liquid 18 within which the electronic device 16 is submerged (within the chamber 28). The liquid then undergoes the second phase heat energy exchange with the HHGDs 19 before being output to heat exchanger 26. The arrangement of FIG. 6 is configured for operation in-series with respect to the first stage heat energy transfer with the initial LHGDs 17 and then the subsequent second stage heat energy transfer with the HHGDs 19 via the segregated/partitioning of the LHGDs 17 from the HHGDs 19 via second housings 20 and the various cooling liquid low pathways.

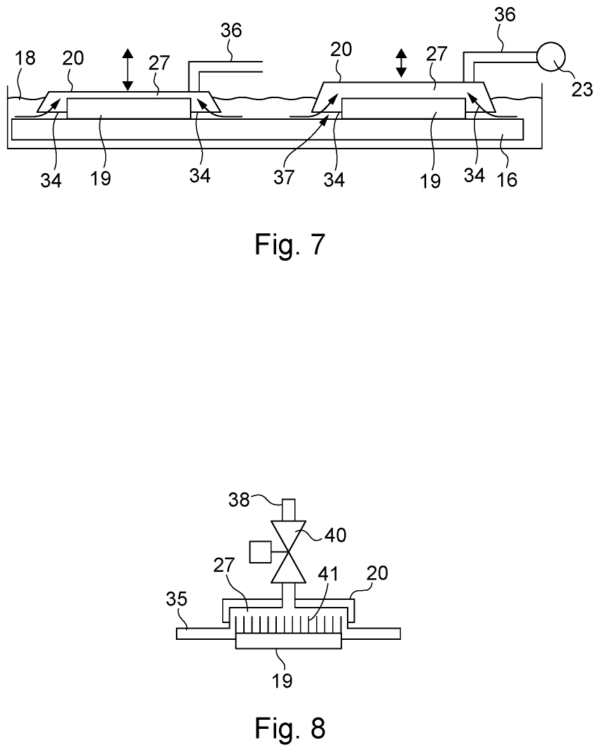

Referring to FIG. 7, according to one implementation, each second housing 20 comprises an opening 37 to allow a HHGD 19 to be enveloped and at least partially accommodated within the internal enclosure 27. The dielectric cooling liquid 18 flows into enclosure 27 under suction via suction pump 31 (FIG. 4) to pass and circulate in direct contact with HHGD 19 within the local partitioned enclosure 27 for heat energy transfer between HHGD 19 and liquid 18. Each HHGD 19 mounted at motherboard 16, in normal use, has varying operational characteristics including in particular processing demand and therefore heat energy output. The present system is adapted to regulate the supply of the cooling liquid on-demand and via an automated or semi-automated response operation with the objective of delivering to the heat exchanger a working liquid heated to a maximum working temperature and at a constant temperature. This flow control (and regulation of the temperature of the dielectric liquid 18) is achieved via the control unit 33 and adjustably mounted second housings 20. In particular, each second housing 20 may be mounted relative to motherboard 16 so as to be capable of moving back and forth (towards and away from) each respective HHGD 19 so as to change an internal volume of each respective enclosure 27 as detailed referring to FIGS. 8 to 10. Referring to FIG. 8, each enclosure 27 and in particular each second housing 20 may comprise a control valve 40 electronically controllable via control unit 33 so as to regulate a flow of the liquid 18 to each enclosure 27 (and each HHGD 19). Conventionally, each device 19 when mounted at the electronic device 16 comprises a main body processor, a thermal interface material, a heat spreader, a second thermal interface material and a heat sink. It is advantageous to minimise such thermal junctions and therefore according to the present apparatus and system, each HHGD 19 may comprise a microprocessor, a thermal interface material and a series of heat spreader fins 41 extending from the microprocessor/thermal interface material upwardly into the enclosure 27. With the microprocessor operating at maximum processing rate and therefore operating at its maximum operational temperature, valve 40 may be controlled to a fully opened position to maximise the flow rate of liquid between inlet and outlet conduits 38, 35.

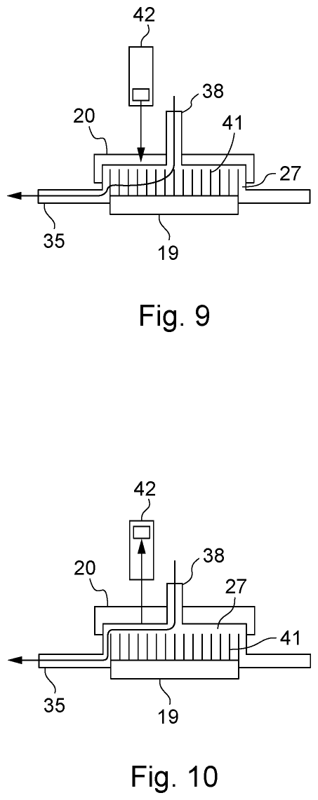

The arrangements of FIGS. 9 and 10 may represent alternative configurations to the valve-controlled arrangement of FIG. 8 or may be a combination of such embodiments and also comprise a corresponding control valve 40 (not shown in FIGS. 9 and 10) optionally mounted at the inlet conduit 38 and/or outlet conduit 35. Referring to FIGS. 9 and 10, an electronically controllable actuator 42 is coupled to second housing 20 that, in turn, may be adjustably mounted at the apparatus via a further support or exclusively via actuator 42. Accordingly, each second housing 20 is capable of a reciprocating motion to and from each HHGD 19. In the minimum volume position of FIG. 9, second housing 20 is located at its closest position relative to HHGD 19. In this position, the dielectric liquid 18 is delivered and forced between the fins 41 for maximum heat energy exchange with HHGD 19. According to the position of FIG. 10, the second housing 20 is raised via actuator 42. In this position, the liquid 18 is allowed to flow around the fins 41 and not necessarily between them so as to decrease the heat energy exchange with HHGD 19 (which may be operating at a lower processing rate and therefore generating less heat). Each actuator 42 is coupled to control unit 33 (as illustrated in FIG. 4) so as to provide local or remote control of the flow rate through the system and in direct contact with the HHGDs 19 in direct response to the operational status of each HHGD 19 (microprocessor) and in particular their respective operational temperatures. Such an arrangement is advantageous to both maximise the heat energy transfer to the liquid 18 from LHGDs 17 and HHGDs 19 but also to moderate the liquid delivered to heat exchanger 26 to be at a constant temperature.

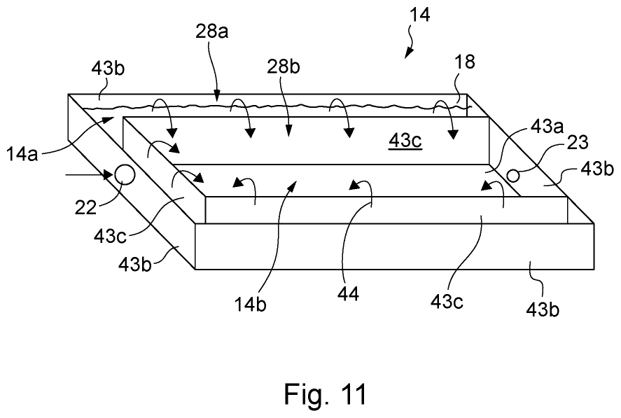

The present apparatus implemented as either an immersion cooling bath of FIG. 1 or a support rack of FIG. 2 may comprise one or a plurality of liquid flow weir arrangements. The weir arrangements may be provided at or towards an inlet of chamber 28 and/or each enclosure 27 and/or at a respective outlet of chamber 28 and/or each enclosure 27. The tray configuration of FIG. 11 may be particularly suitable for the rack embodiment of FIG. 2 in which an electronic device 16 may be at least partially accommodated and positioned within an inner trough 14b relative to a part annular surrounding outer trough 14a. The troughs 14a, 14b are partitioned by a plurality of partition weir walls 46c upwardly extending from a base 43a. The outer trough 14a is further defined by a plurality of outer tray walls 43b also upwardly extending base 43a. A height of walls 43c is preferably slightly less than outer walls 43b such that when liquid 18 is delivered into outer trough 14a via inlet 22, the liquid is configured to overflow from the outer trough 14a into the inner trough 14b via a weir arrangement (over the partition wall 43c). The liquid 18 is allowed to then flows out of the tray 14 via outlet 23.

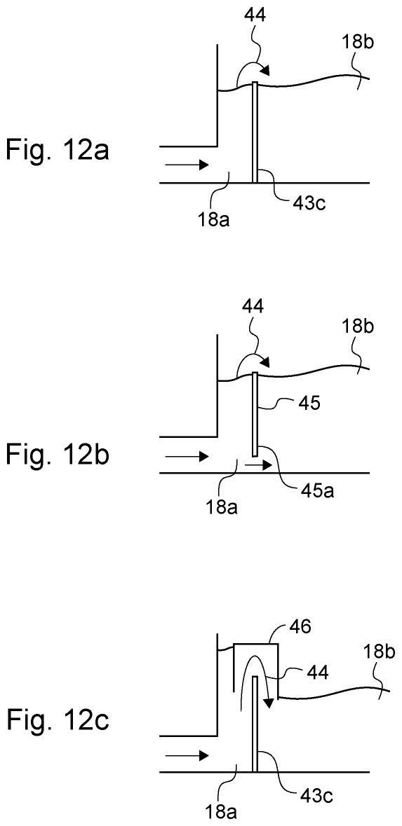

FIGS. 12a, b and c illustrate different configurations of weir arrangements to control the flow of the liquid into the inner trough 14b. FIG. 12a illustrates the arrangement of FIG. 11 with the liquid 18a within outer trough 14a transferring to liquid 18b within inner trough 14b via the weir arrangement 44. According to the embodiment of FIG. 12b, each partition wall 45 separating outer trough 14a from inner trough 14b comprises at least one port 45a to allow the direct flow of liquid 18a within the outer trough 14a to the inner trough 14b (liquid 18b) in addition to the flow over partition wall 45. A syphon-effect weir arrangement is illustrated in FIG. 12c. In this embodiment, a syphon flange 46 extends about the upper end of partition wall 46c so as to define a weir flow conduit between the respective outer and inner troughs 14a, 14b to provide a flow pathway that based on a suction syphon. Each tray 14, each accommodating an electronic device 16 having respective devices 17 and 19 may then be removably stored at the rack 13 via the rails 71 engaging corresponding runners (not shown) provided laterally at each respective tray 14.

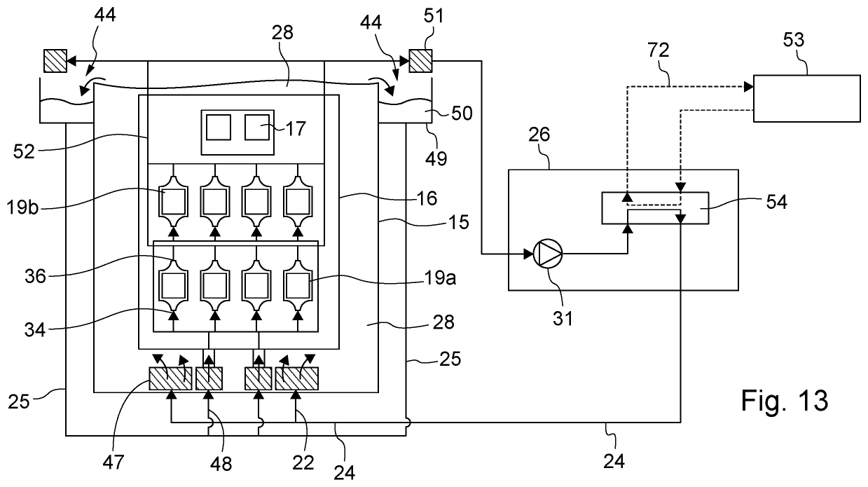

FIG. 13 illustrates a further embodiment of the present cooling apparatus implemented as part of a liquid immersion cooling bath arrangement. Chamber 28 corresponds to the main chamber 12 of bath 10 (FIG. 1) supporting a plurality of electronic devices arranged side-by-side and suspended/immersed within the cooling liquid 18. As illustrated, electronic device 16 may be provided with a plurality of sets of HHGDs 19 that may be arranged and differentiated via their respective operating temperatures and in particular, their respective maximum operating temperatures. In particular, a first set 19a is located towards an inlet 48 and a second set 19b is positioned in a flow direction downstream of the first set 19a further from inlet 48. First set 19a is provided in liquid flow communication with second set 19b via respective ports 36 with the first set 19a being provided in fluid communication with inlet 48 via ports 34. Each HHGD 19 of the first and second set 19a, 19b is partitioned from main chamber 28 via respective second housings 20, with each second housing being optionally adjustably mounted via the arrangements of FIGS. 8 to 10 having a controllable flow of cooling liquid. Primary housing 15 is configured for the inflow of the cooling liquid via inlet 22 which according to the arrangement of FIG. 13 is provided with a plenum 47 to distribute/spread the incoming flow of liquid evenly within chamber 28. Primary housing 15 is provided with at least one respective weir arrangement 44 located at an upper end of bath 10. Accordingly, the cooling liquid is configured to overflow into at least one temporary storage reservoir 49 as a liquid holding volume 50. A gravity return manifold 25 provides fluid communication with the holding volume 50 and inlet 48. The apparatus also comprises an outlet flow conduit network 52 providing fluid communication from the HHGD sets 19a, 19b to heat exchanger 26 via intermediate control valves 51. Heat exchanger 26 may comprise the pump 31 as an integral component or the apparatus may comprise additional pumps at various positions within the liquid flow network. Heat exchanger 26 comprises an internal heat transfer coil 54 coupled with a working fluid network 72 configured to receive heat energy from the dielectric cooling liquid 18. The heated working fluid (within network 72) may then be delivered (as a heat source) to supplementary or auxiliary components 53 within a datacentre and the like within which the present system may be implemented. In operation, the dielectric liquid is initially introduced into chamber 28 via inlets 22 and plenum 47 so as to flow (within chamber 28) upwardly against gravity towards weirs 44. During this pathway, liquid 18 flows in direct contact with the LHGDs 17 such that the liquid overflowing into the holding volume 50 is at partially heated/warmed. The warmed liquid is then returned via manifold 25 to a inlets 48 where it is delivered directly to the first set 19a of HHGDs 19 for a second stage heat transfer. The flow to each HHGD 19 within the first set 19a occurs in parallel. The flow then continues and via an in-series flow from the first set 19a to the second set 19b. Again, the flow at each HHGD 19 within second set 19b occurs in parallel. Accordingly, the present system is configured to provide delivery of the dielectric liquid 18 in-series according to a three stages heat transfer process involving the first stage transfer with the LHGDs 17, the second transfer with the HHGD first set 19a and the third stage transfer with the HHGD second set 19b. The liquid is then supplied to heat exchanger 26 via pump 31 and (via control valves 51) before being recirculated to the chamber 28 via return manifold 24.

The encapsulation of each HHGD 19 and the respective partitioning against other HHGDs 19 and LHGDs 17 increases the temperature differential of the dielectric liquid delivered initially to the bath 10 (at inlets 22) relative to the heated liquid delivered to the heat exchanger device 26. Additionally, via the control unit 33 (FIG. 4) the various sensors 30, control valves 40 and/or actuators 42, the present system are adapted to maximise energy efficiency via an automated or semi-automated dynamically response to the operational status of each HHGD 19 i.e. operating between a minimum and a maximum operating temperature based upon processing rate. The single or various operational characteristics/status of each LHGD and HHGD (i.e. temperature, power generation, processing rate etc) may be monitored and/or fed and utilised by the present system in real-time so as to control the colling liquid 18 (e.g., to regulate liquid flow rate) at the various different regions of the circuit.

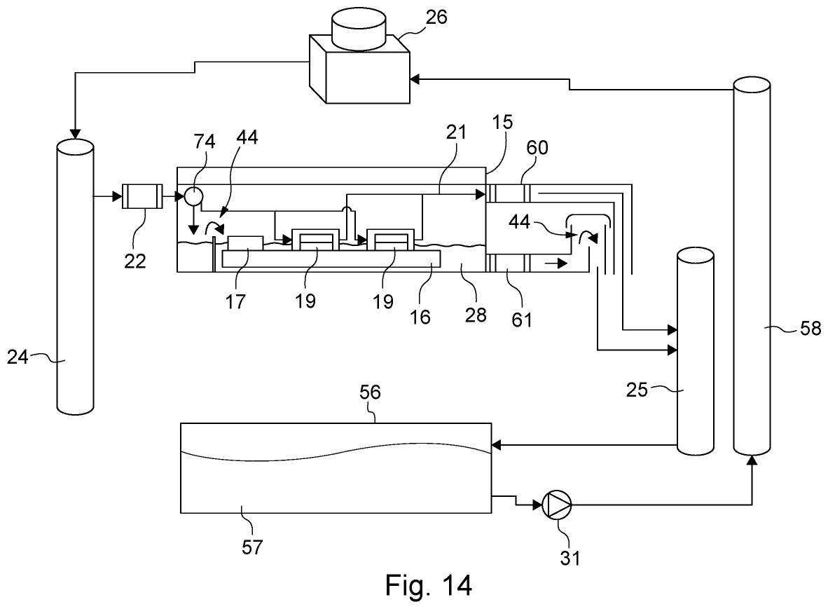

FIGS. 14 to 19 illustrate further specific implementations of a circulating cooling liquid network forming part of the present apparatus and system implemented as either an immersion cooling bath 10 (FIG. 1) or a storage rack 13 (FIG. 2). The arrangements of FIGS. 14 to 19 are configured for further operational control of the fluid flow via additional reservoirs and/or pressurisation tanks at different regions of the system in which the dielectric cooling liquid may be stored temporarily and its temperature and/or pressure adjusted as part of its circulation within the network.

Referring to FIG. 14, the cooling liquid network comprises inlet manifold 24, heat exchanger 26, secondary return manifold 58, gravity return manifold 25, reservoir 56 (containing a stored volume of liquid 57), pump 31 and either an immersion bath or rack and tray arrangement (provided in fluid communication between manifolds 24 and 25). According to the specific implementation, a weir arrangement 44 is provided at an inlet end of chamber 28 so as to regulate a flow of cooling liquid to electronic device 16. LHGDs 17 are at least partially submerged within the cooling liquid for the first heat energy transfer. The cooling liquid is then the output via outlet valve 61 to a second weir arrangement 44 that provides fluid communication to gravity return manifold 25. The liquid is then transferred to reservoir 56 (buffer storage) and is then returned via manifold 58 to heat exchanger 26 for onward flow to the inlet manifold 24 as a cooled liquid. The liquid flow into inlet 22 is diverted via a junction valve 74 to also flow into respective enclosures 27 and in direct contact with HHGDs 19. The combined outflow from enclosures 27 is then routed through conduit 21 between outlet flow valve 60 which is, in turn, is coupled in fluid communication to the gravity return manifold 25 for combined flow with the liquid from valve 61. The liquid within the circuit of FIG. 14 may be pressurised or may be implemented at atmospheric pressure. The system comprises the control unit 33 (not shown) and associated sensors (not shown) as described herein to provide a real-time dynamically responsive liquid cooling system for the advantages mentioned herein.

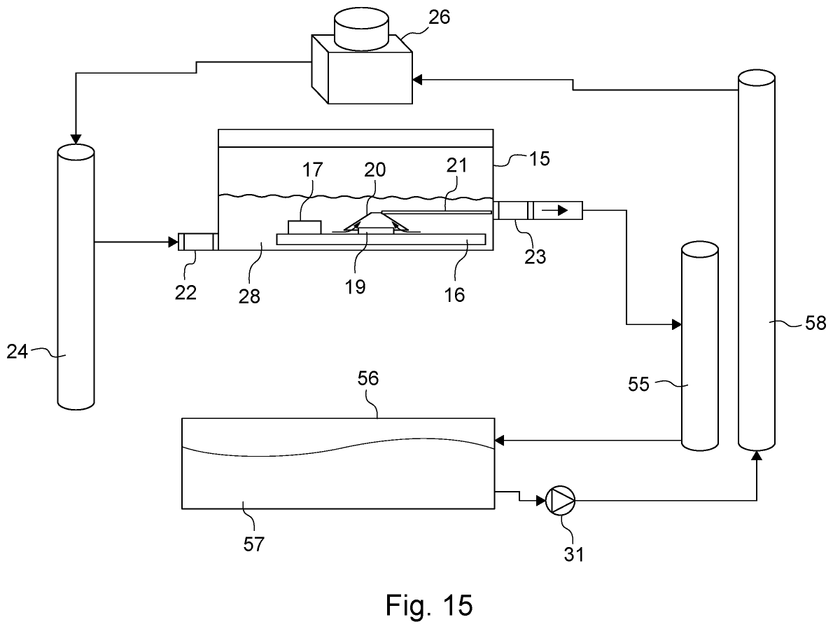

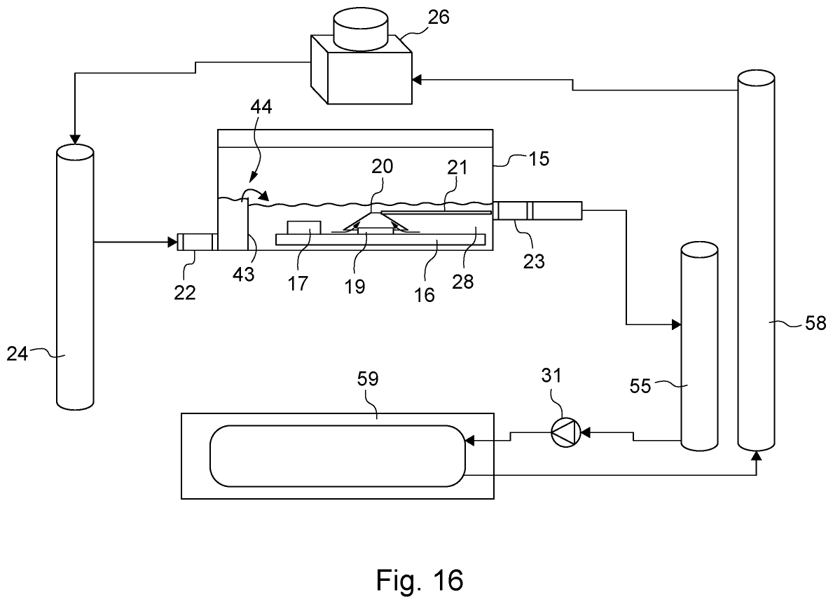

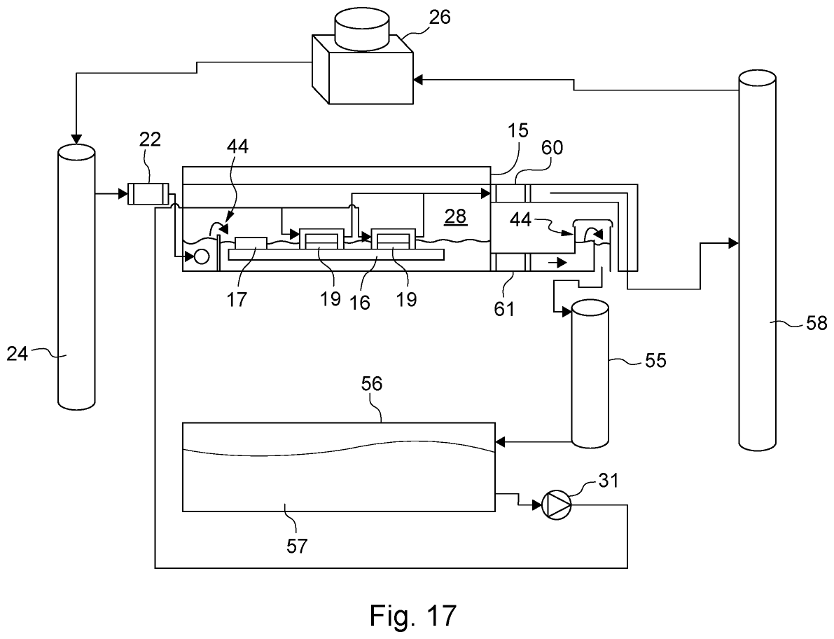

FIG. 15 is a simplified embodiment of the arrangement of FIG. 14 and comprises generally the same components and function including manifolds 24, 55, 58, reservoir 56, pump 31 and heat exchanger 26. According to the embodiment of FIG. 15, the electronic device 16 is housed within a chamber 28 having an inlet and outlet 22, 23 provided in direct flow with the respective manifolds 24, 55. The in-series flow over LHGDs 17 and HHGDs 19 is as described referring to the embodiment of FIG. 3. A further embodiment being a variation of the embodiment of FIG. 15 is illustrated in FIG. 16. A pressurisation vessel 59 is implemented in place of reservoir 56 and an inlet flow weir arrangement 44 is provided at the inlet 22 of the primary housing 15. A further embodiment is illustrated in FIG. 17 in which the storage reservoir 56 is also connected downstream of a return manifold 55 that is, in turn, coupled to the outlet valve 61 of the chamber 28 via an outlet weir arrangement 44. Outlet valve 61 is configured to receive warmed liquid partially heated by LHGDs 17. Outlet valve 60 is configured to receive fully heated liquid from the HHGD 19 for the subsequent delivery to manifold 58 and transfer to heat exchanger 26. As illustrated, the partially warmed liquid (from outlet valve 61) is transferred via manifold 55, reservoir 56 and pump 31 to be delivered to each enclosed HHGD 19 according to a multi-stage in-series heat energy exchange (relative to the initial stage heating by the LHGDs 17).

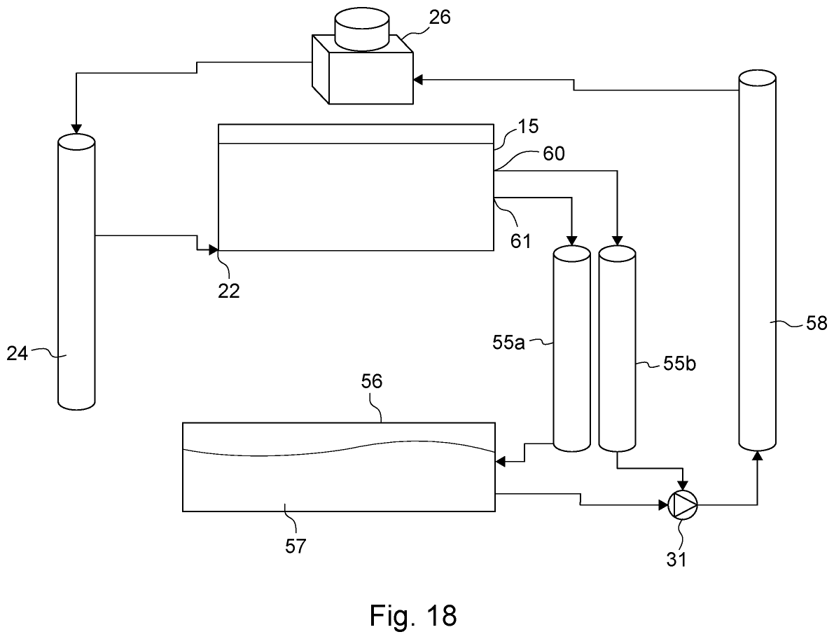

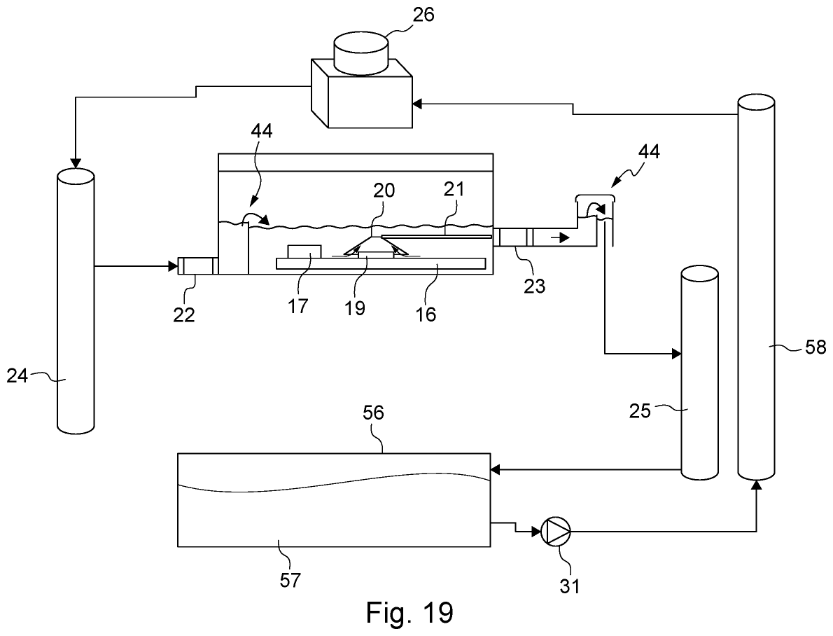

FIG. 18 illustrates a further embodiment of the cooling liquid network being similar to the arrangement of FIG. 17. First stage heating outlet valve 61 is connected to a first return manifold 55a that is in turn coupled to feed storage reservoir 56. A second return manifold 55b is coupled to the second stage outlet valve 60 with an output from manifold 55b connected to pump 31 for transfer to manifold 58 and subsequently to heat exchanger 26 for delivery to inlet manifold 24. Reservoir 56 is also coupled upstream to pump 31 such that the outlet colling liquid flow from valves 61, 60 are combined to flow into the return manifold 58 for heat transfer at heat exchanger 26. FIG. 19 illustrates a yet further embodiment and variation of the arrangement of FIG. 16 having weir arrangement 44 at inlet 22 and also comprising a second weir arrangement 44 at outlet 23 for onward delivery to the return manifold 25 that is provided in fluid communication with storage reservoir 56. The embodiments of FIG. 19 also comprises the pump 31, manifold 58, heat exchanger 26 and inlet manifold 24, as described and coupled in liquid flow communication referring to FIG. 16.

1. Liquid cooling apparatus for an electronic device comprising:
a primary housing defining a chamber to accommodate at least one electronic device having at least one heat-generating electronic component;
at least one liquid flow inlet and at least one liquid flow outlet provided at the housing to allow a flow of a dielectric cooling liquid to enter and exit the chamber in direct contact with the electronic device;
a second housing located within the chamber defining an enclosure to at least partially accommodate the at least one heat-generating electronic component of the device;
at least one liquid flow inlet and at least one liquid flow outlet provided at the second housing to allow a flow of the liquid to enter and exit the enclosure in direct contact with the heat-generating electronic component; and
a cooling unit connected in fluid communication with at least one of the inlets and at least one of the outlets forming part of a fluid flow network to transfer heat energy from the liquid.

2. The apparatus as claimed in claim 1 wherein the at least one outlet of the primary housing is connected in fluid communication to the at least one inlet of the second housing such that the liquid is configured to flow through the chamber and then through the enclosure.

3. The apparatus as claimed in claim 1 comprising an electronic device having:
at least one first heat-generating electronic component at least partially accommodated within the chamber for immersion in the liquid within the chamber; and
at least one second heat-generating electronic component at least partially accommodated within the enclosure for immersion in the liquid within the enclosure.

4. The apparatus as claimed in claim 3 wherein the second heat-generating electronic component is capable of comprises a higher-operating temperature than the first heat-generating electronic component.

5. The apparatus as claimed in claim 4 wherein the at least one outlet of the second housing is connected in fluid communication to an inlet of the cooling unit and an outlet of the cooling unit is connected in fluid communication to the at least one inlet of the primary housing.

6. The apparatus as claimed in claim 5 wherein the chamber is connected in fluid communication in-series with the enclosure.

7. The apparatus as claimed in claim 6 further comprising:
at least one electronically controllable valve provided in fluid communication with the inlet and/or the outlet of the primary housing and/or the second housing; and
a control unit to control the valve and a flow of the liquid to enter and exit the primary housing and/or the second housing via the respective inlet and outlet.

8. The apparatus as claimed in claim 7 wherein the control unit is configured to control the liquid flow through the chamber for a first heat energy exchange with the first heat-generating electronic component and then to control the liquid flow through the enclosure for a second heat energy exchange with the second heat-generating electronic component, the second heat energy exchange being supplemental and additional to the first heat energy exchange such that an increase in a temperature of the liquid at the outlet of the enclosure is a sum of a temperature increase of the liquid having passed through the chamber and the enclosure.

9. The apparatus as claimed in claim 1 wherein the primary housing comprises a liquid immersion tank and the second housing is smaller in size than the primary housing and is located within the chamber.

10. The apparatus as claimed in claim 1 comprising a dielectric cooling liquid contained within the chamber of the primary housing and wherein the second housing is at least partially immersed in or completely submerged by the liquid within the chamber of the primary housing.

11. The apparatus as claimed in claim 10 wherein at least a part of the second heat-generating electronic component is positioned in direct contact with the liquid within the enclosure defined by the second housing and/or at least a part of the first heat-generating electronic component is positioned in direct contact with the liquid within the chamber.

12. The apparatus as claimed in claim 3 wherein the electronic device comprises any one or a combination of:
a computer entity;
a server;
a motherboard;
a printed circuit board comprising a plurality of electronic components.

13. The apparatus as claimed in claim 3 wherein the first heat-generating electronic component and/or the second heat-generating electronic component comprise any one or a combination of:
a motherboard;
random access memory (RAM);
a graphics processing unit (GPU);
a central processing unit (CPU).

14. The apparatus as claimed in claim 1 wherein the inlet of the second housing is defined by at least a perimeter of an opening by which the second housing is positionable to receive and envelope the heat-generating electronic component at the enclosure.

15. The apparatus as claimed in claim 1 wherein the inlet and outlet of the second housing are separate from one another and/or positioned at different regions of the second housing.

16. The apparatus as claimed in claim 1 wherein the second housing comprises an opening to enable the second housing to receive and envelope the heat-generating electronic component at the enclosure and a roof positioned opposite the opening.

17. The apparatus as claimed in claim 16 wherein the inlet of the second housing is positioned at the roof of the second housing.

18. The apparatus as claimed in claim 16 wherein the outlet of the second housing is defined, in part by the opening.

19. The apparatus as claimed in claim 1 further comprising an actuator connected to the second housing to actuate a movement of the second housing, the actuator configured to change any one or a combination of:
an internal volume of the enclosure;
a position of the enclosure relative to the housing and/or the heat-generating electronic component;
a separation distance between the second housing and the heat-generating electronic component;
an extent to which the second housing encapsulates or accommodates the heat-generating electronic component within the enclosure.

20. The apparatus as claimed in claim 1 wherein the second housing is adjustably mounted at the apparatus via an actuator that by actuation is configured to change an internal volume of the enclosure.

21. The apparatus as claimed in claim 1 further comprising a pump connected in fluid communication to the inlet and/or the outlet of the second housing to drive a flow of the liquid through the enclosure.

22. The apparatus as claimed in claim 1 comprising a first electronically controllable valve connected in fluid communication to the inlet and/or the outlet of the chamber and a second electronically controllable valve connected in fluid communication to the inlet and/or the outlet of the enclosure.

23. The apparatus as claimed in claim 1 comprising at least one electronically controllable valve provided in fluid communication with the inlet and/or the outlet of the second housing.

24. The apparatus as claimed in claim 1 comprising at least one temperature sensor to determine a temperature or relative temperature difference of the liquid and/or the heat-generating electronic component, the temperature sensor provided in electronic communication with the control unit.

25. The apparatus as claimed in a claim 3 wherein the electronic device or the first and/or second heat-generating electronic components comprise a temperature sensor to determine a temperature or a temperature difference of the liquid and the first and/or second heat-generating electronic components.

26. The apparatus as claimed in claim 1 further comprising a liquid return conduit connecting in fluid communication the outlet of the chamber and the inlet of the enclosure to circulate the liquid that exits the chamber into the enclosure.

27. The apparatus as claimed in claim 26 further comprising a temporary storage reservoir connected in fluid communication between the outlet of the chamber and the inlet of the enclosure to temporarily store a volume of the liquid for circulation from the chamber to the enclosure.

28. The apparatus as claimed in claim 26 wherein an inlet of the chamber comprises a plenum to distribute a flow of the liquid into the chamber.

29. The apparatus as claimed in claim 1 wherein the cooling unit comprises a heat exchanger to transfer heat energy from the liquid to a heat transfer fluid.

30. The apparatus as claimed in claim 26 wherein the outlet of the primary housing is connected in fluid communication to an inlet of the cooling unit and an outlet of the cooling unit is connected in fluid communication to the inlet of the second housing.

31. The apparatus as claimed in claim 1 comprising a plurality of second housings, each having a respective inlet and outlet connected in fluid communication to the cooling unit.

32. The apparatus as claimed in claim 31 wherein at least some of the second housings are connected in-series with one another as part of a liquid flow network including the cooling unit.

33. The apparatus as claimed in claim 31 wherein at least some of the second housings are connected in-parallel with one another as part of a liquid flow network including the cooling unit.

34. The apparatus as claimed in claim 1 comprising a dielectric cooling liquid contained within the chamber and capable of flowing through the enclosure.

35. The apparatus as claimed in claim 34 comprising an electronic device having:
at least one first heat generating electronic component at least partially accommodated within the chamber for immersion in chamber; and
at least one second electronic component at least partially accommodated within the enclosure for immersion in the liquid within the enclosure, wherein at least a part of the electronic device and/or the at least a part of first heat-generating electronic component is positioned within the chamber and immersed in direct contact with the liquid within the chamber and at least a part of the at least one second heat-generating electronic component is positioned within the enclosure and immersed in direct contact with the liquid within the enclosure.

36. A method of cooling at least part of an electronic device comprising:
immersing an electronic device having at least one heat-generating electronic component within a dielectric cooling liquid contained within a chamber defined by a primary housing;
immersing the heat-generating electronic component within the liquid within an enclosure defined by a second housing located within the chamber;
providing a first flow of the liquid through the chamber via at least one inlet and at least one outlet provided at the primary housing;
providing a second flow of the liquid through the enclosure via at least one inlet and at least one outlet provided at the second housing;
cooling the liquid heated by the electronic device and/or the heat-generating electronic component using a cooling device forming part of a fluid flow network connected in fluid communication to at least one of the inlets and at least one of the outlets.

37. The method as claimed in claim 36 wherein the electronic device comprises at least a first heat-generating electronic component and at least one second heat-generating electronic component that is capable of or comprises a higher operating temperature than the first heat-generating electronic component, wherein at least a part of the second heat-generating electronic component is positioned in direct contact with the liquid within the enclosure defined by the second housing and/or at least a part of the first heat-generating electronic component is positioned in direct contact with the liquid within the chamber.

38. The method as claimed in claims 35 wherein the chamber is connected in fluid communication in-series with the enclosure such that the liquid is configured to flow through the chamber and then to flow through the enclosure.

39. The method as claimed in claim 36 comprising:
plurality of enclosures defined by respective second housings each enclosing a respective heat-generating electronic component provided at the electronic device;
wherein the plurality of enclosures are connected in liquid flow in-series with one another; and
wherein the respective heat-generating electronic components comprise substantially the same operating temperature or comprise different operating temperatures arranged within respective second housings in order of increasing operating temperature such that the liquid is configured to flow through the respective enclosures in contact with the respective heat-generating electronic components in-series from the relative low to high operating temperature.

40. The method as claimed in claim 36 wherein the liquid is configured to flow from the outlet of the chamber to the inlet of the enclosure via a return flow conduit and then the liquid is configured to flow from the at least one outlet of the enclosure to a fluid flow network that includes the cooling unit.

41. The method as claimed in claim 37 comprising controlling a flow of the liquid to flow along the first pathway through the chamber in direct contact with at least a part of the first heat-generating electronic component and then along a second flow pathway through the enclosure in direct contact with at least a part of the second heat-generating electronic component such that heat energy transferred to the liquid is a sum of a heat energy transferred from the first heat-generating electronic component and the second heat-generating electronic component.

42. The method as claimed in claim 36 further comprising driving a flow of the liquid through the chamber and/or the enclosure using a pump.

43. The method as claimed in claim 41 comprising directing a return flow of the liquid from the outlet of the chamber at an end of the first flow pathway to the inlet of the enclosure at a start of the second flow pathway.

44. The method as claimed in claim 43 comprising:
directing the flow of the liquid from the outlet of the enclosure to the cooling unit to reduce the temperature of the liquid; and
providing a return flow of the liquid cooled by the cooling unit to the inlet of the enclosure.

45. The method as claimed in claims 44 comprising temporarily storing the liquid received from the outlet of the chamber at the end of the first flow pathway at a temperature storage reservoir prior to the step of directing the return flow of the liquid to the inlet of the enclosure.

46. The method as claimed in claim 36 wherein the electronic device comprises a plurality of first heat-generating electronic components each immersed in the liquid and a plurality of second housings defining respective enclosures to accommodate the heat-generating electronic components.

47. The method as claimed in claim 46 wherein the liquid flows through the enclosures in direct contact with the heat-generating electronic components and the flow through some of the enclosures is in-series and/or the flow through some of the enclosures is in-parallel.

48. A liquid immersion cooling bath to cool an electronic device having at least one heat-generating electronic component, the bath comprising the apparatus as claimed in claim 1; and
an electronic device having at least one heat-generating electronic component, the device and the heat-generating electronic component immersed respectively within the dielectric cooling liquid contained within the chamber as defined by the primary housing and/or the enclosure as defined by the second housing.

49. The liquid immersion cooling bath as claimed in claim 48 comprising:
at least one primary housing defining the chamber to accommodate the at least one electronic device having at least one heat-generating electronic component;
a plurality of second housings located within the chamber defining respective enclosures to at least partially accommodate respective heat-generating electronic component of the devices; and
a plurality of electronic devices each having at least one heat-generating electronic component, the devices immersed within the liquid contained within the chamber and the at least one heat-generating electronic component immersed within the liquid contained within the respectively enclosures.

50. The liquid immersion cooling bath as claimed in claim 49 wherein the plurality of electronic devices each have first and second heat-generating electronic components, the devices and the first heat-generating electronic components at least partially immersed within or completely submerged by the liquid contained within the primary housing and the second heat-generating electronic components at least partially immersed within or completely submerged by the liquid contained within the enclosures.
